(19) United States
(12) Patent Application Publication
(10) Pub. No.: US 2007/0212649 A1
(43) Pub. Date: Sep. 13, 2007

(54) Method and system for enhanced lithographic patterning

(75) Inventors: Sanjaysingh Lalbahadoersing, Helmond (NL); Sami Musa, Eindhoven (NL)

Correspondence Address: PILLSBURY WINTHROP SHAW PITTMAN, LLP, P.O. BOX 10500, MCLEAN, VA, 22102, US

(73) Assignee: ASML Netherlands B.V., Veldhoven (NL)

(21) Appl. No.: 11/369,222

(22) Filed: Mar. 7, 2006

(51) Int. Cl. G03F 7/20

(52) U.S. Cl. 430/312; 430/311; 430/394

(57) ABSTRACT

A double patterning system and process using a carbon-based hard mask. The double patterning system provides a means to form hard mask features in single hard mask etch step with a feature spacing smaller than a minimum spacing printable in the hard mask based on a single exposure.

### FIELD OF THE INVENTION

The invention relates to a system and method of enhancing pattern transfer in lithography. More particularly, the invention relates to a hard mask system with variable mask properties.

### BACKGROUND OF THE INVENTION

The invention is directed to the field of lithography and lithographic projection apparatus that encompass a radiation system for supplying a projection beam of radiation, a support structure for supporting a patterning device, which serves to pattern the projection beam according to a desired pattern, a substrate table for holding a substrate; and, a projection system for projecting the patterned beam onto a target portion of the substrate.

The term “patterning device” as employed here should be broadly interpreted as referring to devices that can be used to endow an incoming radiation beam with a patterned cross-section, corresponding to a pattern that is to be created in a target portion of the substrate. The term “light valve” can also be used in this context. Generally, the pattern will correspond to a particular functional layer in a device being created in the target portion, such as an integrated circuit or other device. Examples of such patterning devices include:
A mask. The concept of a mask is well known in lithography and it includes mask types such as binary, alternating phase-shift, and attenuated phase-shift, as well as various hybrid mask types. Placement of such a mask in the radiation beam causes selective transmission (in the case of a transmission mask) or reflection (in the case of a reflective mask) of the radiation impinging on the mask, according to the pattern on the mask. In the case of a mask, the support structure will generally be a mask table, which ensures that the mask can be held at a desired position in the incoming radiation beam, and that it can be moved relative to the beam if so desired;
A programmable mirror array. One example of such a device is a matrix-addressable surface having a visco-elastic control layer and a reflective surface. The basic principle behind such an apparatus is that addressed areas of the reflective surface reflect incident light as diffracted light, for example, whereas unaddressed areas reflect incident light as non-diffracted light. Using an appropriate filter, the non-diffracted light can be filtered out of the reflected beam leaving only the diffracted light behind. In this manner, the beam becomes patterned according to the addressing pattern of the matrix-addressable surface. An alternative embodiment of a programmable mirror array employs a matrix arrangement of tiny mirrors, each of which can be individually tilted about an axis by applying a suitable localized electric field or by employing piezoelectric actuators. Once again, the mirrors are matrix-addressable, such that addressed mirrors will reflect an incoming radiation beam in a different direction to unaddressed mirrors. In this manner, the reflected beam is patterned according to the addressing pattern of the matrix-addressable mirrors. The required matrix addressing can be performed using suitable electronic circuitry.

In both of the situations described here above, the patterning device can comprise one or more programmable mirror arrays. More information on mirror arrays as here referred to can be gleaned, for example, from U.S. Pat. No. 5,296,891 and U.S. Pat. No. 5,523,193, and PCT patent applications WO 98/38597 and WO 98/33096, which are incorporated herein by reference. In the case of a programmable mirror array, the support structure may be embodied as a frame or table, for example, which may be fixed or movable as required; and
A programmable LCD array. An example of such a construction is given in U.S. Pat. No. 5,229,872, which is incorporated herein by reference. As above, the support structure in this case may be embodied as a frame or table, for example, which may be fixed or movable as required.

For purposes of simplicity, the rest of this text may, at certain locations, specifically direct itself to examples involving a mask and mask table. However, the general principles discussed in such instances should be seen in the broader context of the patterning device as set forth here above.

Lithographic projection apparatus can be used, for example, in the manufacture of integrated circuits (ICs). In that case, the patterning device may generate a circuit pattern corresponding to an individual layer of the IC. This pattern can be imaged onto a target portion (e.g. comprising one or more dies) of a substrate (silicon wafer) that has been coated with a layer of radiation-sensitive material (resist). In general, a single wafer will contain a whole network of adjacent target portions that are successively irradiated via the projection system, one at a time. In current apparatus that employ patterning by a mask on a mask table, a distinction can be made between two different types of machines. In one type of lithographic projection apparatus, each target portion is irradiated by exposing the entire mask pattern onto the target portion in one exposure. Such an apparatus is commonly referred to as a wafer stepper or step-and-repeat apparatus.

In an alternative apparatus, commonly referred to as a step-and-scan apparatus, each target portion is irradiated by progressively scanning the mask pattern under the projection beam in a given reference direction (the “scanning” direction), while synchronously scanning the substrate table parallel or anti-parallel to this direction. Since, in general, the projection system will have a magnification factor M (generally <1), the speed V at which the substrate table is scanned will be a factor M times that at which the mask table is scanned. More information with regard to lithographic devices as here described can be gleaned, for example, from U.S. Pat. No. 6,046,792, incorporated herein by reference.

In a manufacturing process using a lithographic projection apparatus, a pattern (e.g. in a mask) is imaged onto a substrate that is at least partially covered by a layer of radiation-sensitive material (resist). Prior to this imaging step, the substrate may undergo various procedures, such as priming, resist coating and a soft bake. After exposure, the substrate may be subjected to other procedures, such as a post-exposure bake (PEB), development, a hard bake and measurement/inspection of the imaged features. This array of procedures is used as a basis to pattern an individual layer of a device, e.g. an integrated circuit (IC). Such a patterned layer may then undergo various processes such as etching, ion-implantation (doping), metallization, oxidation, chemical-mechanical polishing, etc., all intended to finish off an individual layer. If several layers are required, then the whole procedure, or a variant thereof, will have to be repeated for each new layer. Eventually, an array of devices will be present on the substrate (wafer). These devices are then separated from one another by a technique such as dicing or sawing, whence the individual devices can be mounted on a carrier, connected to pins, etc. Further information regarding such processes can be obtained, for example, from the book “Microchip Fabrication: A Practical Guide to Semiconductor Processing”, Third Edition, by Peter van Zant, McGraw Hill Publishing Co., 1997, ISBN 0-07-067250-4, incorporated herein by reference.

For the sake of simplicity, the projection system may hereinafter be referred to as the “lens”. However, this term should be broadly interpreted as encompassing various types of projection system, including refractive optics, reflective optics, and catadioptric systems, for example. The radiation system may also include components operating according to any of these design types for directing, shaping or controlling the projection beam of radiation, and such components may also be referred to below, collectively or singularly, as a “lens”.

Furthermore, the lithographic apparatus may be of a type having two or more substrate tables (and/or two or more mask tables). In such “multiple stage” devices the additional tables may be used in parallel, or preparatory steps may be carried out on one or more tables while one or more other tables are being used for exposures. Dual stage lithographic apparatus are described, for example, in U.S. Pat. No. 5,969,441 and WO 98/40791, both incorporated herein by reference.

Although specific reference may be made in this text to the use of the apparatus according to the invention in the manufacture of integrated circuits, it should be explicitly understood that such an apparatus has many other possible applications. For example, it may be employed in the manufacture of integrated optical systems, guidance and detection patterns for magnetic domain memories, liquid-crystal display panels, thin-film magnetic heads, etc. The person skilled in the art will appreciate that, in the context of such alternative applications, any use of the terms “reticle”, “wafer” or “die” in this text should be considered as being replaced by the more general terms “mask”, “substrate” and “target portion”, respectively.

In this document, the terms “radiation” and “projection beam” are used to encompass all types of electromagnetic radiation, including ultraviolet (UV) radiation (e.g. with a wavelength of 365, 248, 193, 157 or 126 nm) and extreme ultra-violet (EUV) radiation (e.g. having a wavelength in the range 5-20 nm), among others.

For lithographic processing, the location of patterns in subsequent layers on the wafer should be as precise as possible for a correct definition of device features on the substrate, which features all should have sizes within specified tolerances. The overlay should be within well-defined tolerances for creating functional devices. To this end, the lithographic projection apparatus comprises an overlay measurement module which provides for determining the overlay of a pattern on the substrate with a mask pattern, as defined in a resist layer on top of the pattern.

The overlay system typically performs the measurement by optical elements. The position of the mask pattern relative to the position of the pattern located on the substrate is determined by measuring an optical response from an optical marker that is illuminated by an optical source. The signal generated by the optical marker is measured by a sensor arrangement. The overlay may be derived from output of the sensors.

Optical markers are used during microelectronic device processing (or IC processing) along the full manufacturing line. During the front end of line (FEOL), markers are used for overlay during manufacturing of transistor structures, for example. At a later stage during the back end of line (BEOL), markers are needed for overlay of metallization structures, e.g. connect lines, and vias. It is noted that in both cases, the integrity of the markers should be sufficient to meet the required accuracy of overlay.

### SUMMARY

In one embodiment of this invention, a method for pattern transfer includes a first step of providing a hard mask layer on a surface of a substrate. Preferably, the hard mask layer is diamondlike carbon. In a second step a patterned radiation beam is provided toward the hard mask layer when the substrate is located at a first horizontal position with respect to the patterned radiation beam. For example, the patterned beam of radiation can be light, such as UV or visible wavelength radiation, that is passed through a physical mask. Alternatively, the patterned beam of radiation can be a beam formed by reflecting light, such as visible or UV radiation, from a micromirror array, or using a light valve system. First portions of the hard mask layer are exposed to a first dose of radiation from the patterned radiation beam, wherein the first dose is sufficient to substantially change etch characteristics of the first portions. The patterned beam and substrate are relatively displaced with respect to each other over a distance to a second position. Preferably the distance is less than a minimum feature pitch that is printable on the hard mask using the patterned beam of radiation in a single exposure. Second portions different from the first portions of the hard mask layer to are exposed to a second dose of radiation from the patterned radiation beam, wherein the second dose is sufficient to substantially change etch characteristics of the second portions. In a further step, the hard mask layer is subjected to an etch process, wherein the first and second portions are substantially removed, and wherein portions of the hard mask layer other than the first and second portions are substantially intact. Accordingly a hard mask can be fabricated having features spaced at distances less than the minimum feature pitch printable in a single exposure.

In one embodiment of the present invention, a method for pattern transfer comprises a first step of providing a radiation-sensitive hard mask layer on the substrate. The substrate can be any surface having any combination of layers, patterned features, or device structures. Preferably the hard mask layer is an amorphous carbon layer. In a second step, a patterned beam of radiation configured to produce a feature spacing (D) is provided at a first position of the substrate, wherein first portions of the hard mask layer are exposed to an etch enhancing radiation dose. Preferably the etch enhancing radiation dose is received from a visible light or UV radiation source. The patterned beam of radiation is provided at a second position of the substrate that is displaced from the first position by a distance less than D, wherein second portions of the hard mask layer are exposed to an etch enhancing radiation dose. In an additional step, the hard mask layer is subject to an etch, wherein the first and second portions are configured to etch substantially faster than unirradiated portions of the hard mask layer after receiving an etch enhancing dose. In one embodiment of the present invention, the distance between the first and second positions is about D/2. Accordingly, the inventive process provides a hard mask with features characterized by a spacing about one half that provided in a single exposure process, using a single hard mask etch step and no photoresist processing to define the hard mask.

In one configuration of this invention, a system for enhanced lithographic patterning of a substrate includes a lithographic apparatus configured to supply a patterned beam of radiation. Preferably, the patterned beam of radiation is configured to produce a feature spacing (D) in a substrate in a single exposure. In one configuration, the patterned beam of radiation is provided by passing visible or UV radiation through a mask. In another configuration, the patterned beam of radiation is formed by a maskless means for generating a patterned beam. The system further includes a substrate table for holding a substrate having a hard mask disposed thereon. A controller is provided that is configured to change the relative position of the substrate with respect to the patterned beam of radiation for a exposure to a first dose of radiation at a first position and a second dose of radiation at a second. Preferably, the displacement between the first and second positions is less than the feature spacing provided by the patterned beam of radiation. The mutual displacement between the first position and second position can be accomplished by movement of the substrate table, movement of the patterned beam, or both. Portions of the hard mask receiving the first and second radiation doses are configured to etch in an etch process at a substantially faster rate that unirradiated portions of the hard mask. In this manner, patterned features can be etched into the hard mask by a selective etch of the hard mask, wherein the minimum separation of patterned features is smaller than the minimum feature pitch defined by the patterned beam of radiation in a single exposure.

In one configuration of the present invention, the patterned beam of radiation used in a first exposure is the same as the patterned beam or radiation used in the second exposure. In another configuration of this invention, the patterned beam of radiation used in the first exposure differs from that used in the second exposure, wherein features printed in the hard mask in the first exposure differ from features printed from the hard mask printed in the second exposure. In a preferred embodiment of the latter configuration, a patterned beam of radiation used for the first and second exposures is produced by a maskless means for generating a patterned beam, such as a programmable micromirror array that can be programmed to produce different beam patterns.

In one aspect of the invention, the hard mask material is used in conjunction with a double exposure lithography process that uses two exposures from a single mask. Preferably, the hard mask material as initially applied to the substrate is amorphous carbon that has substantially diamond-like carbon properties. In one configuration of the invention, an amorphous carbon hard mask material has substantial resistance to removal by O₂ plasma ashing or related plasma etching processes. Upon exposure to an etch enhancing radiation dose, portions of the amorphous carbon hard mask material so exposed become substantially graphitized. Preferably, the radiation dose is from visible light or UV radiation such as that emitted from an excimer laser source at 248 or 193 nm wavelengths. In one aspect, the areas of the hard mask that are substantially graphitized by the radiation are selectively removed by a plasma process such as O₂ plasma ashing. Accordingly, a double exposure process can be used to pattern features into a hard mask that have a density higher than that afforded by a single exposure, wherein the double exposure process can be completed with a single selective etch step of the hard mask.

### BRIEF DESCRIPTION OF THE DRAWINGS

FIG. 1 illustrates a lithographic projection apparatus that includes at least one marker structure.

FIG. 2 schematically illustrates a computer arrangement according to one embodiment of the invention.

FIGS. 3a-c illustrate features of a reference process used to help clarify features of the present invention.

FIGS. 4-4c illustrate exemplary features involved in a double patterning system, according to one embodiment of the present invention.

### DETAILED DESCRIPTION OF THE EMBODIMENTS OF THE INVENTION

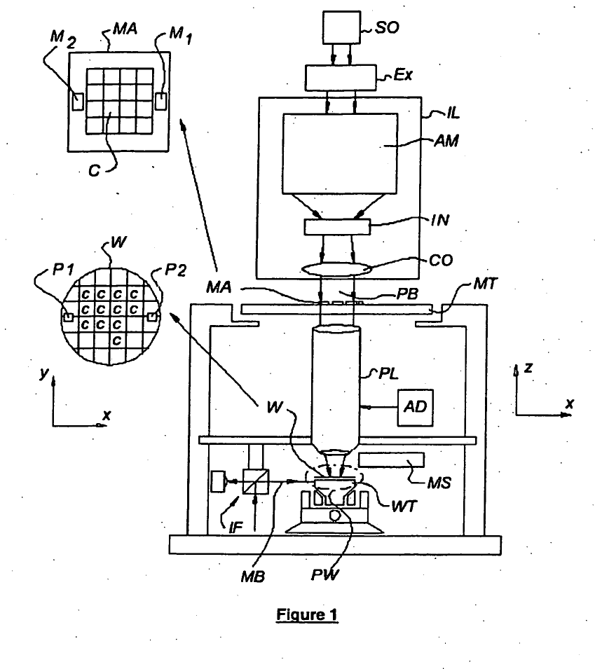

FIG. 1 schematically depicts lithographic projection apparatus that includes at least one marker structure in accordance with an embodiment of the invention. The apparatus includes:
an illumination system IL for providing a projection beam PB of radiation (e.g. UV or EUV radiation). In this particular case, the radiation system also includes a radiation source SO;
a first support structure MT (e.g. a mask table) for supporting a patterning device, MA (e.g. a mask) and connected to a first positioner (not shown) for accurately positioning the patterning device with respect to item PL;
a second support structure WT (e.g. a wafer table) for holding a substrate, W (e.g. a resist-coated silicon wafer) and connected to a second positioner PW for accurately positioning the substrate with respect to item PL; and
a projection system PL (e.g. a reflective projection lens) for imaging a pattern imported to the projection beam PB by patterning device MA onto a target portion C (e.g. comprising one or more dies) of the substrate W.

The projection system PL is provided with an actuating device AD for adjusting settings of the system. The operation of adjusting settings will be explained hereinafter in more detail.

As depicted here, the apparatus is of a transmissive type (i.e. has a transmissive mask). However the apparatus may alternatively be of a reflective type (with a reflective mask). Alternatively the apparatus may employ another kind of patterning device, such as a programmable mirror array of a type as referred to above.

The source SO (e.g. a mercury lamp or an excimer laser) produces a beam of radiation. This beam is fed into an illumination system (illuminator) IL, either directly or after having traversed conditioning elements, such as a beam expander Ex, for example. The illumination system IL further conditions the beam, and may include adjustable optical elements AM for setting the outer and/or inner radial extent (commonly referred to as σ-outer and σ-inner, respectively) of the intensity distribution of the beam PB. In addition, it will generally include various other components, such as an integrator IN and a condenser CO. In this way, the beam PB impinging on the mask MA includes a desired uniformity and intensity distribution in its cross-section.

It should be noted with regard to FIG. 1 that the source SO may be within the housing of the lithographic projection apparatus (as is often the case when the source SO is a mercury lamp, for example). Alternatively, the source SO may be remote from the lithographic projection apparatus, the beam which it produces being led into the apparatus (e.g. with the aid of suitable directing mirrors). This latter scenario is often the case when the source SO is an excimer laser. The invention is applicable to both of these scenarios.

The beam PB is incident on the mask MA, which is held on the mask table MT. Having traversed the mask MA, the beam PB passes through the lens PL, which focuses the beam PB onto a target portion C of the substrate W. With the aid of the second positioner PW and interferometer IF, the substrate table WT can be moved accurately, e.g. so as to position different target portions C in the path of the beam PB. Similarly, the first positioner (acting on the mask table MT) can be used to accurately position the mask MA with respect to the path of the beam PB, e.g. after mechanical retrieval of the mask MA from a mask library, or during a scan. In general, movement of the object tables MT, WT will be realized with the aid of a long-stroke module (coarse positioning) and a short-stroke module (fine positioning), which are not explicitly shown in FIG. 1. However, in the case of a wafer stepper (as opposed to a step-and-scan apparatus) the mask table MT may just be connected to a short stroke actuator, or may be fixed. Mask MA and substrate W may be aligned using mask alignment marks M1, M2 and substrate alignment marks P1, P2.

The depicted apparatus can be used in two different modes:

1. In step mode, the mask table MT and the substrate table WT are kept essentially stationary and an entire pattern imported to the beam PB is projected in one operation (i.e. a single “flash”) onto a target portion C. The substrate table WT is then shifted in the X and/or Y directions so that a different target portion C can be irradiated by the beam PB; and

2. In scan mode, essentially the same scenario applies, except that a given target portion C is not exposed in a single “flash”. Instead, the mask table MT is movable in a given direction (the so-called “scan direction”, e.g. the Y-direction) with a speed ν, so that the projection beam PB is caused to scan over a mask image; concurrently, the substrate table WT is simultaneously moved in the same or opposite direction at a speed V=M ν, in which M is the magnification of the lens PL (typically, M=¼ or ⅕). In this manner, a relatively large target portion C can be exposed, without having to compromise on resolution.

3. In another mode, the mask table MT is kept essentially stationary holding a programmable patterning device, and the substrate table WT is moved or scanned while a pattern imparted to the projection beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

In a non-illustrated variant embodiment, the substrate table may be replaced by a twin-scan arrangement that includes two scan stages to which the wafers are supplied successively. While one of the wafers is being exposed in one or other of the different modes described above, another of the wafers is being subjected to the necessary measurements to be carried out prior to exposure, with a view to decreasing the amount of time that each wafer is within the exposure zone and thus increasing the throughput of the system. More generally, the lithographic apparatus may be of a type having two or more substrate tables (and/or two or more mask tables). In such multiple stage machines, the additional tables may be used in parallel or preparatory steps may be carried out on one or more tables while one or more other tables are being used for exposure.

The interferometer typically includes a light source, such as a laser (not shown), and one or more interferometers for determining some information (e.g. position, alignment, etc.) regarding an object to be measured, such as a substrate or a stage. In FIG. 1, a single interferometer IF is schematically depicted by way of example. The light source (laser) produces a metrology beam MB which is routed to the interferometer IF by one or more beam manipulators. In a case where more than one interferometer is provided, the metrology beam may be shared between them, by using optics that split the metrology beam into separate beams for the different interferometers.

A substrate alignment system MS for aligning a substrate on table WT with a mask on mask table MT is schematically shown at an exemplary location close to the table WT, and includes at least one light source which generates a light beam aimed at a marker structure on the substrate W and at least one sensor device that detects an optical signal from that marker structure. It is to be noted that the location of the substrate alignment system MS depends on design conditions that may vary with the actual type of lithographic projection apparatus.

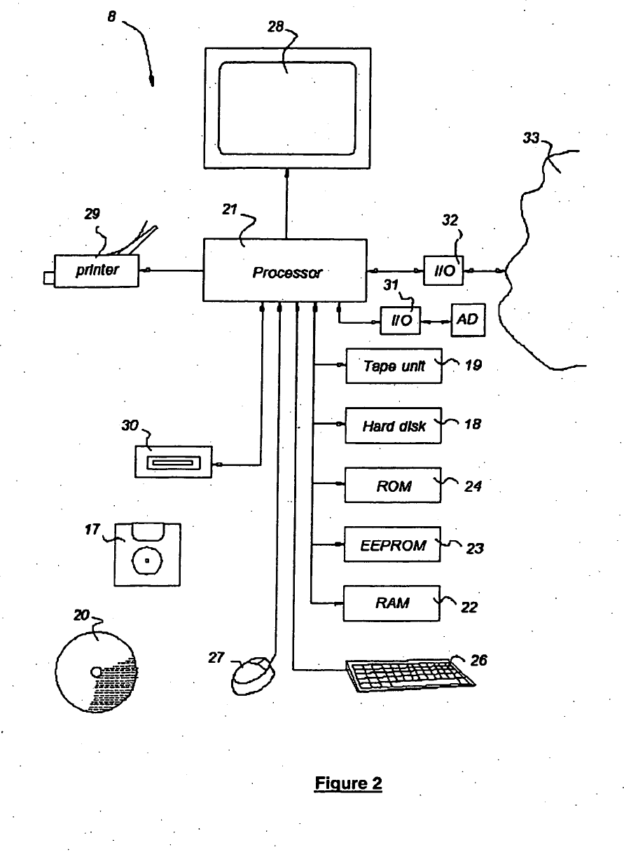

Furthermore, the lithographic projection apparatus includes an electronic control system that is capable of controlling and adjusting machine setting during execution of an imaging and exposure process. An exemplary electronic control system is schematically illustrated in FIG. 2. It is noted that the lithographic projection apparatus includes sophisticated computing resources for controlling functions of the lithographic projection apparatus with high accuracy. FIG. 2 illustrates only the functionality of the computing resources in relation to the invention. The computing resources may include additional systems and subsystems which are not illustrated here.

Machine setting may be adjusted to compensate for focus offset by displacing the projected image in the vertical (z) direction. Alternatively, machine setting may be adjusted to improve alignment by laterally shifting the image position in the horizontal plane (the x,y-plane).

FIG. 2 schematically illustrates a computer arrangement 8 as used in a particular embodiment of the invention that includes a host processor 21 with peripherals. The host processor 21 is connected to memory units 18, 19, 22, 23, 24 which store instructions and data, one or more reading units 30 (to read, e.g. floppy disks 17, CD ROM's 20, DVD's, etc.), input devices, such as a keyboard 26 and a mouse 27, and output devices, such as a monitor 28 and a printer 29. Other input devices, like a trackball, a touch screen or a scanner, as well as other output devices, may be provided.

An input/output (I/O) device 31 is provided for connection to the lithographic projection apparatus. The I/O device 31 is arranged for handling signals transmitted to and received from actuators and sensors, which take part in controlling projection system PL in accordance with the invention. Further, a network I/O device 32 is provided for a connection to a network 33.

The memory units include a RAM 22, an (E)EPROM 23, a ROM 24, a tape unit 19, and a hard disk 18. However, it should be understood that other memory units may be provided that are known to persons skilled in the art. Moreover, one or more of the memory units may be physically located remote from the processor 21. The processor 21 is shown as one box, however, it may comprise several processing units functioning in parallel or controlled by one main processor, that may be located remotely from one another, as is known to persons skilled in the art.

Furthermore, computer arrangement 8 may be located remotely from the location of the lithographic projection apparatus and may provide functions to the lithographic projection apparatus over a further network connection.

The projection system is provided with an actuating device AD which is capable of adjusting optical settings of the projection system by manipulating the optical elements and stage positions within the projection system. The actuating device AD is provided with input and output ports for exchanging control signals with a control system (not shown). The computer arrangement 8 of the invention is capable of controlling and adjusting the settings of the projection system in such a way that, during an exposure, the overlay displacement of features is made as low as possible. It should be noted that the computer arrangement 8 may receive status signals from the lithographic projection apparatus which relate to the status and/or the settings of the projection system and/or other parts of the lithographic projection apparatus. As will be appreciated by persons skilled in the art, the status signals may influence the timing and/or response of the electronic control system.

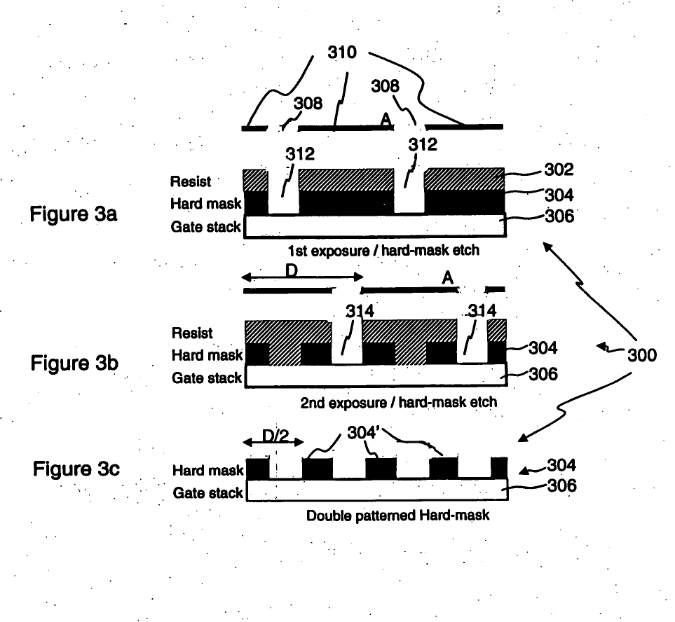

FIGS. 3a-c illustrate features of a reference process used to help clarify features of the present invention. Stack 300 is illustrative of a sequence of layers that can be used in lithographic patterning of a substrate, such as substrate layer 306. In the particular example depicted, substrate layer 306 could be a gate stack layer on a silicon wafer. In order to pattern features into substrate layer 306, in initial steps (not shown) a hard mask layer 304 and resist layer 302 can be applied. During a first patterning step depicted in FIG. 3a, a mask 310 is used to pattern resist layer 302 and hard mask layer 304, as shown. The patterning can be accomplished by exposure of resist layer 302 to radiation through apertures 308 in mask 310. The radiation can be 248 nm or 193 nm UV radiation, for example, which chemically alters areas of resist that receive the radiation, such that the irradiated areas can be selectively preserved, or selectively etched (as depicted in FIG. 3a) by a subsequent etch process, leaving patterned features. In a step subsequent to patterning of resist layer 302 the openings in layer 302 are used to etch layer 304 beneath layer 302, as depicted in FIG. 3a.

Hard masks, such as layer 304 have become increasingly important for patterning processes as the size of features to be patterned becomes smaller, for example, in advanced electronics components. Patterned photoresist layers, such as a layer 302 can be used as mask layers themselves, so that layers underneath the patterned resist layer can be etched. However, typical etch processes that are used with patterned resist layers for the purpose of selectively etching the underlying substrate layers, (such as silicon, silicon oxide, and the like) typically etch the resist layer at a faster rate. Thus, the thickness of the underlying substrate layer that can be etched is limited by the thickness of the resist layer, which could completely disappear during etching if the substrate layer being etched is too thick. However, as the required feature pattern shrinks, the thickness of resist layers must also be reduced, in order to preserve the integrity of pattern transfer into layers underneath the resist and to prevent collapse of tall and narrow resist features.

In view of such competing problems, the use of hard masks affords the ability to etch smaller features. By use of hard mask 304, in conjunction with resist layer 302, fine features can be etched. Hard mask layers are typically thinner than resist layers because the hard mask layers can be designed from materials that have a much higher etch selectivity with respect to underlying substrate layers than does a typical resist layer, such as PMMA. Accordingly, a relatively thin layer of resist can be used to first pattern a thin hard mask layer. The thickness of the hard mask layer is sufficiently low that after initial patterning of the resist layer, the resist can survive during the subsequent etch of the hard mask layer. In a later step, the underlying substrate layer can be etched with the patterned hard mask layer used as a mask, so that the substrate is etched in the openings in the hard mask layer. The high etch selectivity of the hard mask layer allows the thinner hard mask layer to survive for the etch time necessary to etch the underlying substrate.

In spite of the use of hard masks to afford etching of smaller features, limitations on the minimum size of features than can be etched into a substrate are imposed by, among other things, the wavelength of light used to irradiate and pattern the mask material. Based on lithography tool parameters such as numerical aperture, the minimum pitch between adjacent features that can be printed on a substrate (“minimum feature pitch”) is limited for a given wavelength of light used. The minimum pitch used in lithography masks (taking into account the demagnification from the mask to the substrate) is generally selected according to the minimum feature pitch printable using the lithography tool employing the mask, since any mask features corresponding to smaller pitches would not print out on the substrate. Thus, for a given lithography apparatus, a mask or set of masks used to produce a given patterned beam of radiation, is typically configured with mask features that are designed to produce structures in a substrate that have a feature pitch equal to or larger than the minimum feature pitch printable by the lithography apparatus.

In view of the above limitations, as the required separation (minimum feature pitch required) between devices shrinks in advanced electronic technologies, it becomes increasingly difficult to fabricate such devices using conventional single exposure processes, in which a substrate is exposed to a patterned beam of radiation in a single exposure. For example, for sub-90 nm device sizes, it is increasingly difficult to pattern features using 248 or 193 nm radiation.

In order to increase the amount of structures on a substrate, so that structures can be spaced at distances below the minimum feature pitch associated with a lithography tool used to pattern the substrate, a technique such as double exposure can be employed, as illustrated in FIGS. 3a-3c. As noted above, FIG. 3a represents a process stage in which an initial exposure and removal of exposed resist regions has taken place, followed by a hard mask etch step. The patterning of the resist/hard mask stack 302/304 takes place when mask region A is near the center of the Figure. The process stage depicted in FIG. 3b occurs after an additional layer of resist has been added to coat openings 312, followed by a shifting in mask 310, as depicted by the position of region A. Subsequent patterning and etching of resist/hard mask layers 302/304 results in new openings 314. In FIG. 3c, resist 302 has been selectively removed leaving patterned hard mask 304 with features 304′ separated by distance D′. Thus, a mask configured to produce a feature pitch D in a single exposure, can be used to pattern and form a hard mask with feature pitch D′˜D/2. It will be appreciated, however, that the process outlined in FIGS. 3a-3c requires two separate resist layer depositions, two exposure steps of resist 302 and two etching steps of hard mask 304.

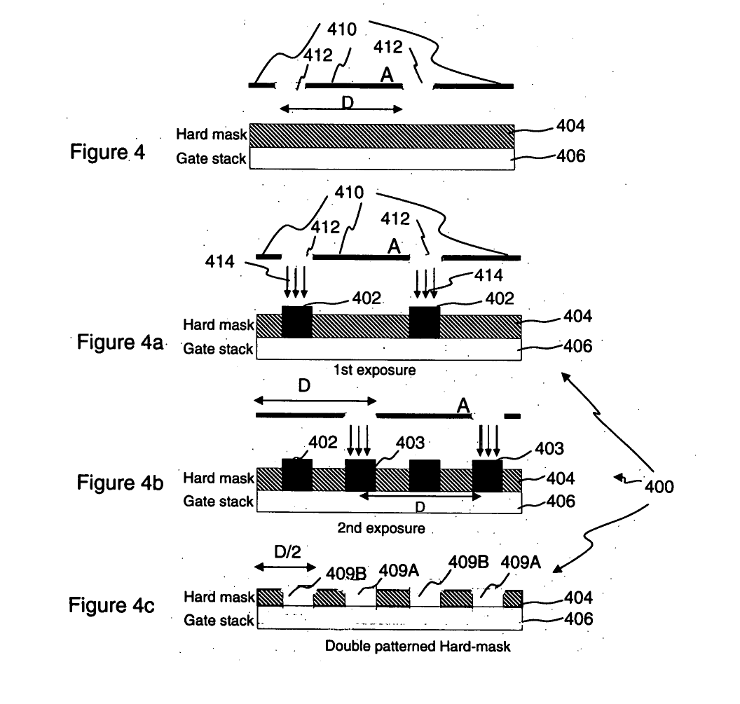

FIGS. 4-4c illustrate exemplary features involved in a system and method for enhanced pattern transfer, according to one configuration of the present invention. Stack 400 includes a hard mask layer 404 and substrate 406. Preferably, layer 404 is an amorphous carbon material. As used herein, the term “amorphous carbon” refers to a material having a high carbon content ( preferably having greater than 50% carbon). Amorphous carbon can typically contain a substantial component of hydrogen, in some cases approaching, but preferably not exceeding 50%. One defining feature of the material referred to as “amorphous carbon” herein, is that it has a substantial diamondlike character. The diamondlike character can be shown by measurement of optical properties, bond-type measurements of carbon atoms, and other physical measurements. The amorphous carbon also typically has a component of graphite-like character that can be determined from similar physical measurements. Typically, amorphous carbon has little or no crystalline order. Typically, the intermixing of diamondlike and graphite-like regions within amorphous carbon occurs on a very intimate scale, usually on the scale of a nanometer or less such that the unirradiated amorphous carbon material appears homogenous on the length scale of a patterned feature (currently greater than about 50 nm).

In the configuration shown in FIGS. 4-4c, a double exposure patterning process similar to that depicted in FIGS. 3a-3c is performed. Thus, a physical mask 410 configured to produce a feature separation D in a substrate (hard mask) using a single exposure, can be used to produce a hard mask 404 having a feature separation D/2. However, the process steps involved in reaching the patterned hard mask structure of FIG. 4c are substantially reduced.

In FIG. 4, a single layer hard mask 404 preferably is amorphous carbon. As deposited, the amorphous carbon layer is substantially as described above. The amorphous carbon layer can be deposited by known techniques, such as chemical vapour deposition, plasma enhanced chemical vapour deposition, and physical vapour deposition. As depicted in FIG. 4, a mask 410 is provided with apertures 412 that are configured to provide a patterned beam of radiation having a features spacing D. After exposure to UV radiation, as illustrated in FIG. 4a, for example, using an excimer laser, portions 402 become irradiated. It has recently been shown that laser irradiation of diamondlike carbon results in graphitization (see Seth, et al., Thin Solid Films 254 (1995) 92-95). Accordingly, regions 402 are substantially graphitelike. At the step depicted in FIG. 4b, the above outlined process used to produce the structure of FIG. 4a has been repeated. In this case, mask 410 is shifted a distance equal to one half D. For example, a controller in a lithography tool used for the double exposure process could shift a substrate table by a distance equal to D/2 after a first exposure. It will be appreciated that the distance D/2 is typically a “horizontal” shift along the x-direction, y-direction, or a combination of the two as defined in FIG. 1. In the case where a physical mask is used to provide the patterned beam or radiation, regions 403 can be formed with substantially the same dimension as regions 402. In other words, because apertures 412 are used in both exposures illustrated in FIGS. 4a and 4b, the dimensions of irradiated regions should 403 and 402 should be about equal for equivalent irradiation conditions.

In FIG. 4c, a selective etch process has been performed, such that regions 402, 403 are removed, leaving patterned layer 404 with a feature pitch of D/2. Because irradiated portions 402, 403 are substantially graphitized, an etch in an O₂ plasma (plasma ashing) can be used to etch the irradiated portions. Is has been shown that graphitized material can be etched faster than unirradiated amorphous carbon (See Seth, et al.). For example, for an initial amorphous carbon thickness of about 500 nm that is subject to 248 nm wavelength radiation, exposure to 100 pulses at a fluence of 400 mJ/cm2 creates an etch rate ratio of exposed amorphous carbon-to-unexposed amorphous carbon of about 3.5 using O₂ reactive ion etching. It will be appreciated that the terms “O₂ plasma”, “O₂ reactive ion etching”, “O₂ ashing” refer to reactive ion etching processes that contain a high fraction, though not necessarily single species, of O₂ gas.

In another embodiment of this invention, the steps illustrated in FIGS. 4, 4a and 4b could be performed using a maskless means for generating the patterned beam of radiation. For example, radiation beamlets 414 that constitute a patterned beam of radiation, could be generated by reflection of light from micromirror array elements (not shown) or by passing light through an array of light valves (not shown). A controller that controls a means for generating a maskless patterned beam of radiation could be used to shift the maskless patterned radiation beam by the distance D/2 between the steps illustrated by FIGS. 4a and 4b. Alternatively, a substrate table controller could be used to shift the substrate containing the hard mask layer between the exposure steps illustrated in FIGS. 4a and 4b, while the beamlets 414 created by the micromirror array remain stationary.

According to one aspect of the present invention, by appropriate choice of layer thickness of layer 404, and by appropriate choice of an etch-enhancing radiation dose, both portions 402, 403 can be completely removed in an etch while a substantial portion of unirradiated layer 404 remains as a hard mask. The term “etch-enhancing radiation dose”, as used herein, refers to an amount of radiation based on the radiation wavelength and material properties of the hard mask, that is sufficient to induce a significant increase in the hard mask etch rate as compared to unirradiated portions of the hard mask. For example, a radiation dose that increases the etch rate of irradiated hard mask portions by 25-50% (with respect to unirradiated portions) could be considered a moderately etch-enhancing dose, while a dose that increases the etch rate by 200% could be considered a substantially etch-enhancing dose. Because the above process outlined in FIGS. 4a-4c requires only a single hard mask etch after exposure of portions 402 and 403, the enhancement of etch rate of the exposed portions need not be severe for embodiments of the present invention to operate. As an example, for a 200 nm thick amorphous carbon hard mask layer, portions 402 and 403 could be subjected to an etch-enhancing dose that increases the etch rate by 100%. During subsequent O₂ ashing, the time at which portions 402 and 403 would be completely removed would correspond to removal of about 100 nm of the unirradiated hard mask portions. Even using 20% overetch to ensure complete removal of portions 402 and 403, 80 nm of unirradiated hard mask would remain, which could be more than sufficient to withstand a subsequent etch performed to transfer the patterned features 409 into a substrate. Accordingly, the double exposure process depicted in FIGS. 4a-c can be accomplished using only two lithographic exposure steps and a single etch step. Moreover a wide radiation does “process window” exists in which a radiation dose can be varied and still be effective in enhancing the etch rate of regions 402 and 403 sufficient for the structure of FIG. 4c to be fabricated.

It is to be noted that the pitch D that corresponds to a feature pitch printable on a substrate for a given patterned radiation beam (for example, a beam passing through a mask), need not be the minimum feature pitch that is possible from a given lithography tool. For example, it may be known that a given 248 nm tool is capable of printing a minimum feature pitch of 120 nm in a single exposure. Based on this knowledge, if a minimum feature pitch of 100 nm were desired in a wafer, a mask for the lithography tool could be designed for 200 nm minimum feature pitch, and subjected to the double exposure process outlined above, wherein a 100 nm feature pitch is produced on the wafer. This allows printing of structures whose nominal single exposure minimum pitch is well within tool capabilities, while still fabricating structures of feature pitch below the single exposure minimum feature pitch.

In other configurations of the invention, where a patterned beam of radiation is characterized by a minimum feature pitch D that is printable in a single exposure, the horizontal displacement of a substrate between positions of a first and a second exposure to the patterned beam can be a value different than D/2, for example D/3.

In still another configuration of the invention, a third exposure of a hard mask layer to a patterned beam can be performed at a third positions. For example, relative positions of exposures could be at zero, D/3, and 2D/3 with respect to a dimension D in the patterned beam of radiation.

It is also to be noted that a double exposure process as disclosed with reference to FIG. 4a can result in two different characteristic pitches. For example, referring again to FIG. 4b, the relative displacement between features 402 and 403 could be D/3, in which case, the array of patterned features 402,403 could be characterized by a pitch D, between, for example, neighbouring 403 features, as well as a pitch D/3 between adjacent 402,403 pairs.

It is further to be noted that the feature spacing referred to by D herein, is not limited to a feature “pitch” wherein the term pitch denotes a regular spacing between features that is repeated multiple times. The term D can refer to a feature spacing or minimum feature spacing that is characteristic of just one pair of features or a few features, rather than a regular spacing between features that is repeated multiple times.

In addition, although some embodiments disclosed above generally are directed to multiple exposures using a patterned beam or radiation that can have substantially the same pattern in each of the exposures, embodiments of this invention are possible in which the pattern of the patterned beam of radiation differs between exposures. For example, a first exposure to a patterned beam of radiation might be used to pattern elongated gate features into a hard mask with a spacing D between gate features, while a second exposure is used to pattern different features, such as squares. The square features of the second exposure might also have a spacing of D which is shifted by D/2 from the gate features. This “heterogeneous” double exposure patterning of a hard mask could be accomplished, for example, using a programmable micromirror array. Thus, features 402 can in general be different in size and shape than features 403.

The above methods and systems can be used in conjunction with any patterning (“mask”) level employed in patterning a substrate using a patterned beam of radiation. For example, the mask level could be a metal level or alternatively, a gate level. Each different mask level can be associated with a different minimum wafer pitch D. In addition, the relative horizontal displacement of the patterned beam of radiation between two different exposures need not be in relation to a minimum pitch, but could represent an absolute displacement value or be in relation to another feature of the patterned beam of radiation. For example, the horizontal displacement could be based on design rules that prescribe minimum separation of features. In another configuration of the present invention, a system for pattern transfer includes a lithographic system having a radiation source and a patterning device, such as a mask, wherein a patterned beam of radiation is projected onto a substrate. A radiation-sensitive hard mask material is provided as a coating on a top surface of the substrate. The term “radiation-sensitive hard mask material”, as used herein, refers to a hard mask material whose properties can be readily altered by exposure to electromagnetic radiation, generally in the visible or ultraviolet spectrum. The term “hard mask” as used herein, refers to a layer disposed on a substrate that, in comparison to typical photoresist materials, is generally more resistant to mechanical deformation and to certain etch processes used to etch substrate materials, and can be more thermally stable than photoresist materials. Preferably, the radiation-sensitive hard mask material is an amorphous carbon material whose graphitelike content can increase substantially in regions exposed to the UV radiation incident on the substrate from the patterned beam of UV light. The lithographic system additionally includes a substrate table and a controller that provides for a double exposure process of the radiation-sensitive hard mask material. Preferably, the controller is configured to position the substrate at a first position relative to a patterned beam of radiation for a first exposure of the hard mask material (disposed on a substrate) to the patterned beam of UV radiation; and to position the substrate at a second position relative to a patterned beam of radiation for a second exposure of the hard mask material, wherein the distance between first and second positions is equal to less than a minimum pitch D, for example, D/2. In one configuration of this invention, a controller causes a substrate table to move a distance D/2 between exposures. In another configuration of this invention, a controller is used to shift the position of a patterned beam of radiation by a distance D/2 between exposures, while a substrate table remains fixed. Accordingly, a double exposed pattern of irradiated features in the hard mask material can be created, wherein a minimum pitch between patterned features is D/2. By proper choice of radiation dose used for the first and second exposures, as well as selective etch conditions, a patterned hard mask can be created having openings located at the positions of the irradiated features and spaced by D/2, using a single etch step.

According to a further aspect of the present invention, a double exposure process using an amorphous carbon hard mask can be performed with conventional alignment marks located underneath the carbon hard mask layer. In one exemplary step, patterning of the amorphous carbon layer is performed, such that regions of the hard mask layer that cover alignment marks are left unexposed. Accordingly, those regions retain substantial diamond-like character after the hard mask patterning step. It is known that diamondlike carbon is highly transmissive to light at wavelengths used to perform alignment. Accordingly, alignment can be performed readily by visualization of alignment marks underneath the unirradiated carbon mask.

In another configuration of the present invention, a system for pattern transfer includes a lithographic system having a radiation source and a patterning device, such as a mask, wherein a patterned beam of radiation is projected onto a substrate. A radiation-sensitive hard mask material is provided as a coating on a top surface of the substrate. The term “radiation-sensitive hard mask material”, as used herein, refers to a hard mask material whose properties can be readily altered by exposure to electromagnetic radiation, generally in the visible or ultraviolet spectrum. The term “hard mask” as used herein, refers to a layer disposed on a substrate that, in comparison to typical photoresist materials, is generally more resistant to mechanical deformation and to certain etch processes used to etch substrate materials, and can be more thermally stable than photoresist materials. Preferably, the radiation-sensitive hard mask material is an amorphous carbon material whose graphitelike content can increase substantially in regions exposed to the UV radiation incident on the substrate from the patterned beam of UV light. The lithographic system additionally includes a substrate table and a controller that provides for a double exposure process of the radiation-sensitive hard mask material. Preferably, the controller is configured to position the substrate at a first position relative to a patterned beam of radiation for a first exposure of the hard mask material (disposed on a substrate) to the patterned beam of UV radiation; and to position the substrate at a second position relative to a patterned beam of radiation for a second exposure of the hard mask material, wherein the distance between first and second positions is equal to less than a minimum pitch D, for example, D/2. In one configuration of this invention, a controller causes a substrate table to move a distance D/2 between exposures. In another configuration of this invention, a controller is used to shift the position of a patterned beam of radiation by a distance D/2 between exposures, while a substrate table remains fixed. Accordingly, a double exposed pattern of irradiated features in the hard mask material can be created, wherein a minimum pitch between patterned features is D/2. By proper choice of radiation dose used for the first and second exposures, as well as selective etch conditions, a patterned hard mask can be created having openings located at the positions of the irradiated features and spaced by D/2, using a single etch step.

In accordance with one embodiment of the present invention, a method for pattern transfer in which a patterned radiation beam is provided toward a hard mask layer provided on a substrate when the substrate is at a first position relative to the patterned beam, wherein first portions of the hard mask layer are exposed to a first dose of radiation from the patterned radiation beam, is characterized by the steps of: exposing second portions different from the first portions of the hard mask layer to a second dose of radiation from the patterned radiation beam, the first and second dose sufficient to enhance etch characteristics of the respective first and second portions; and subjecting the hard mask layer to an etch process, wherein the first and second portions are substantially removed, and wherein portions of the hard mask layer other than the first and second portions are substantially intact.

In accordance with another embodiment of this invention, a method for pattern transfer in a substrate in which a radiation-sensitive hard mask layer is provided on the substrate, wherein a patterned beam of radiation configured to produce a feature spacing (D) is provided at a first position of the substrate, wherein first portions of the hard mask layer are exposed to an etch enhancing radiation dose, is characterized by the steps of: providing the patterned beam of radiation at a second position of the substrate that is displaced from the first position by a distance less than D, wherein second portions of the hard mask layer are exposed to an etch enhancing radiation dose; and subjecting the hard mask layer to an etch, wherein the first and second portions are configured to etch substantially faster than unirradiated portions of the hard mask layer after receiving an etch enhancing dose.

In accordance with another embodiment of this invention, a system for pattern transfer includes a lithographic apparatus means configured to supply a patterned beam of radiation, the patterned beam of radiation configured to produce a feature spacing in a substrate in a single exposure; a substrate table means for holding a substrate having a hard mask disposed thereon; and a controller means configured to change a relative position between the substrate and the patterned beam of radiation for exposure to a first dose of radiation at a first relative position and as second dose of radiation at a second relative position, characterized by a displacement between the first and second positions being less than the feature spacing, wherein portions of the hard mask receiving the first and second radiation doses are configured to etch in an etch process at a substantially faster rate that unirradiated portions of the hard mask.

While the preferred forms of the invention have been disclosed, it will be apparent to those skilled in the art that various changes and modifications may be made that will achieve some of the advantages of the invention without departing from the spirit and scope of the invention. It will be apparent to those reasonably skilled in the art that other components performing the same function may be suitably substituted. Further, the methods of the invention may be achieved in either all software implementations, using the appropriate processor instructions, or in hybrid implementations that utilize a combination of hardware logic and software logic to achieve the same results. Therefore, the scope of the invention is to be determined solely by the appended claims.

We claim:

1. A method for pattern transfer, comprising:
providing a patterned radiation beam toward a hard mask layer provided on a substrate,
exposing first portions of the hard mask layer to a first dose of radiation from the patterned radiation beam, the first dose sufficient to enhance etch characteristics of the first portions;
exposing second portions different from the first portions of the hard mask layer to a second dose of radiation from the patterned radiation beam, the second dose sufficient to enhance etch characteristics of the second portions; and
subjecting the hard mask layer to an etch process, wherein the first and second portions are substantially removed, and wherein portions of the hard mask layer other than the first and second portions are substantially intact.

2. The method of claim 1, wherein the hard mask layer is amorphous carbon having a substantial content of diamondlike carbon before exposure to the radiation beam.

3. The method of claim 2, wherein the patterned radiation beam comprises one of 248 nm, 193 nm, and 157 nm UV radiation generated from an excimer laser.

4. The method of claim 2, wherein the first and second doses are substantially the same.

5. The method of claim 2, wherein the first and second doses are each sufficient to substantially graphitize the respective first and second portions.

6. The method of claim 2, wherein the etch process is an O₂ reactive ion etching process, and wherein an etch rate ratio of irradiated to unirradiated portions of the hard mask layer is greater than about two.

7. The method of claim 1, further comprising relatively displacing the substrate and patterned radiation beam over a horizontal displacement after exposing the first portions and before exposing the second portions.

8. The method of claim 7, wherein the patterned radiation beam has a minimum feature pitch that is printable on the hard mask in a single exposure, and wherein the horizontal displacement is less than the minimum feature pitch.

9. The method of claim 8, wherein the horizontal displacement is about one half the minimum feature pitch.

10. The method of claim 2, further comprising relatively displacing the substrate and patterned radiation beam over a horizontal displacement after exposing the first portions and before exposing the second portions, wherein the patterned radiation beam has a minimum feature pitch that is printable on the hard mask in a single exposure, and wherein the horizontal displacement is less than the minimum feature pitch.

11. The method of claim 10, wherein the horizontal displacement is about one half the minimum feature pitch.

12. The method of claim 1, further comprising exposing third portions different from the first and second portions of the hard mask layer to a third dose of radiation from the patterned radiation beam before subjecting the hard mask layer to an etch process, the third dose sufficient to substantially change etch characteristics of the third portions, wherein the third portions are substantially removed during the etch process.

13. A method for pattern transfer, comprising:
providing a radiation-sensitive hard mask layer on a substrate;
providing a patterned beam of radiation configured to produce a feature spacing on the hard mask layer at a first relative position between the substrate and the patterned beam of radiation, wherein first portions of the hard mask layer are exposed to an etch enhancing radiation dose;
providing the patterned beam of radiation at a second relative position between the substrate and the patterned beam of radiation that is displaced from the first relative position by a distance less than D, wherein second portions of the hard mask layer are exposed to an etch enhancing radiation dose; and
subjecting the hard mask layer to an etch, wherein the first and second portions are configured to etch substantially faster than unirradiated portions of the hard mask layer after receiving an etch enhancing dose.

14. The method of claim 13, wherein the hard mask layer is amorphous carbon having a substantial portion of diamondlike carbon in unirradiated regions.

15. The method of claim 14, wherein the amorphous carbon layer comprises between about 90 and 50% carbon and between about 10 and 50% hydrogen.

16. The method of claim 14, wherein the amorphous carbon layer is formed by one of chemical vapor deposition, plasma enhanced chemical vapor deposition, and physical vapor deposition.

17. The method of claim 14, wherein the distance between the first position and second position is about one half the feature spacing.

18. The method of claim 13, wherein the feature spacing is a minimum feature spacing printable in the hard mask using the patterned beam of radiation in a single exposure.

19. The method of claim 13, wherein features of the first portions differ from features of the second portions of the hard mask layer.

20. The method of claim 13, further comprising leaving portions of the hard mask layer that cover alignment marks unexposed during exposure of the hard mask to the patterned beam of radiation at the first and second positions.

21. A system for pattern transfer, comprising:
a lithographic apparatus configured to supply a patterned beam of radiation, the patterned beam of radiation configured to produce a feature spacing in a substrate in a single exposure;
a substrate table for holding a substrate having a hard mask disposed thereon; and
a controller configured to change a relative position between the substrate and the patterned beam of radiation for exposure to a first dose of radiation at a first relative position between the substrate and the patterned beam of radiation and a second dose of radiation at a second relative position between the substrate and the patterned beam of radiation, a displacement between the first and second positions being less than the feature spacing, wherein portions of the hard mask receiving the first and second radiation doses are configured to etch in an etch process at a substantially faster rate that unirradiated portions of the hard mask.

22. The system of claim 21, wherein the hard mask layer is amorphous carbon having a substantial content of diamondlike carbon before exposure to the radiation beam.

23. The system of claim 21, wherein the patterned radiation beam comprises one of 248 nm, 193 nm, and 157 nm UV radiation generated from an excimer laser.

24. The system of claim 21, wherein the etch process is an O₂ reactive ion etching process, and wherein an etch rate ratio of irradiated to unirradiated portions of the hard mask layer is greater than about two.

25. The system of claim 21, wherein the controller is a substrate table controller configured to move the substrate between the first and second positions.

26. The system of claim 21, wherein the controller is a controller for a maskless means for generating the patterned beam of radiation, the controller configured to shift the patterned beam of radiation between the first and second positions.

27. The system of claim 21, wherein the patterned beam of radiation has a first configuration at the first relative position and a second configuration at the second relative position.
